(19) United States
(12) Patent Application Publication
(10) Pub. No.: US 2011/0102214 A1
(43) Pub. Date: May 5, 2011

(54) ROTATION ANGLE DETECTING DEVICE AND DRIVE UNIT

(75) Inventor: Toshiaki UDA, Miyoshi-city (JP)

(73) Assignee: DENSO CORPORATION, Kariya-city (JP)

(21) Appl. No.: 12/898,933

(22) Filed: Oct. 6, 2010

(30) Foreign Application Priority Data
Nov. 5, 2009 (JP) 2009-254025

(51) Int. Cl. H03M 1/48; H02P 7/00

(52) U.S. Cl. 341/116; 318/490

(57) ABSTRACT

A rotation angle detecting device for a motor includes a first capacitor connected in parallel with a first winding of a rotor of the motor, and a second capacitor connected in parallel with a second winding of the rotor. The second capacitor has a capacitance different from that of the first capacitor. A rotation angle calculator of the rotation angle detecting device counts a number of amplitude changes of current detected by a current detector. The rotation angle calculator increases or decreases a value of the counting in accordance with a rotation direction detected by a rotation direction detector.

### CROSS REFERENCE TO RELATED APPLICATION

This application is based on Japanese Patent Application No. 2009-254025 filed on Nov. 5, 2009, the disclosure of which is incorporated herein by reference in its entirety.

### BACKGROUND OF THE INVENTION

1. Field of the Invention

The present invention relates to a rotation angle detecting device, and a drive unit.

2. Description of Related Art

JP-A-2007-6560 discloses a rotation angle detecting device to detect a rotation angle of a motor. The motor has a shaft, a commutator mounted to an end portion of the shaft, and two brushes connected to the commutator. When the shaft has a rotation, electric connection state between the two brushes is changed, thereby a pulse signal is output. The rotation angle of the motor is detected by counting a number of the pulse signals.

However, the rotation angle detecting device is arranged separately from a stator and a rotor of the motor, such that a size of the detecting device may become larger. Further, the detecting device cannot detect a direction of the rotation. For example, when the motor is made to be rotated in opposite direction by an external force, the detection of the rotation angle may not be accurate.

### SUMMARY OF THE INVENTION

In view of the foregoing and other problems, it is an object of the present invention to provide a rotation angle detecting device and a drive unit.

According to a first example of the present invention, a rotation angle detecting device to detect a rotation angle of a motor includes a first capacitor, a second capacitor, a direct current power source, an alternate current power source, a current detector, a rotation direction detector and a rotation angle calculator. The motor includes a stator to form a magnetic field, a rotor having windings, and a brush. The rotor is rotated relative to the stator by electricity supplied to the windings through the brush. The first capacitor is connected in parallel with a first winding of the windings. The second capacitor is connected in parallel with a second winding of the windings. The second capacitor has a capacitance different from a capacitance of the first capacitor. The direct current power source supplies electricity to the windings. The alternate current power source is superimposed with the direct current power source. The current detector detects a current flowing through a circuit defined by the motor. The rotation direction detector detects a rotation direction of the rotor based on an order of amplitude change of the current detected by the current detector. The rotation angle calculator counts a number of the amplitude changes. The rotation angle calculator increases or decreases a value of the counting in accordance with the rotation direction detected by the rotation direction detector, so as to calculate a rotation angle of the rotor or a rotation angle of an object to be driven by the motor.

Accordingly, the rotation angle can be accurately detected.

According to a second example of the present invention, a drive unit includes a stator to form a magnetic field; a rotor to be rotated relative to the stator, the rotor having at least three windings; a commutator electrically connected to the windings of the rotor; at least two brushes to be electrically connected to the commutator; a first capacitor connected in parallel with a first winding of the windings; a second capacitor connected in parallel with a second winding of the windings, the second capacitor having a capacitance different from a capacitance of the first capacitor; a direct current power source to supply electricity to the windings; an alternate current power source superimposed with the direct current power source; a current detector to detect a current flowing through a circuit defined between the two brushes; a rotation direction detector to detect a rotation direction of the rotor based on an order of amplitude change of the current detected by the current detector; and a rotation angle calculator to count a number of the amplitude changes. The rotation angle calculator increases or decreases a value of the counting in accordance with the rotation direction detected by the rotation direction detector, so as to calculate a rotation angle of the rotor or a rotation angle of an object to be driven by the rotor.

Accordingly, the rotation angle can be accurately detected.

At least three electric circuits having different impedances are formed between the at least two brushes, due to the first and second capacitors. Therefore, the current detected by the current detector has at least three states having different amplitudes. The rotation angle detector detects the rotor to have a rotation in a normal direction, if the state of the current is changed in order of a first status, a second status and a third status. The rotation angle detector detects the rotor to have a rotation in an adverse direction, if the state of the current is changed in order of the first status, the third status and the second status. Amplitudes of the currents are different from each other among the first, second and third statuses.

Further, the current detected by the current detector has the at least three statuses relative to a single rotation of the rotor. Therefore, a resolution for detecting the rotation angle can be raised. Further, the rotation angle detecting device can be integrated with the motor. Therefore, a size of the rotation angle detecting device can be made smaller, and a size of the motor can be made smaller.

### BRIEF DESCRIPTION OF THE DRAWINGS

The above and other objects, features and advantages of the present invention will become more apparent from the following detailed description made with reference to the accompanying drawings. In the drawings:

FIG. 1 is a schematic view illustrating a rotation angle detecting device of an embodiment;

FIG. 2 is a schematic cross-sectional view illustrating a motor having the rotation angle detecting device;

FIG. 3 is a perspective view illustrating a rotor of the motor;

FIG. 4 is a schematic view illustrating a varistor of the rotation angle detecting device;

FIG. 5 is a first circuit diagram of the rotation angle detecting device;

FIG. 6 is a second circuit diagram of the rotation angle detecting device;

FIG. 7 is a third circuit diagram of the rotation angle detecting device;

FIG. 8 is a current waveform view of the rotation angle detecting device;

FIG. 9 is a pulse waveform view of the rotation angle detecting device;

FIG. 10 is a logic circuit of the rotation angle detecting device;

FIG. 11 is a truth table of the rotation angle detecting device;

FIG. 12 is a schematic cross-sectional view illustrating an intake air control system having the rotation angle detecting device;

FIG. 13 is a schematic view illustrating a rotation angle detecting device of a comparison example; and

FIG. 14 is a current waveform view of the rotation angle detecting device of the comparison example.

### DETAILED DESCRIPTION OF PREFERRED EMBODIMENT

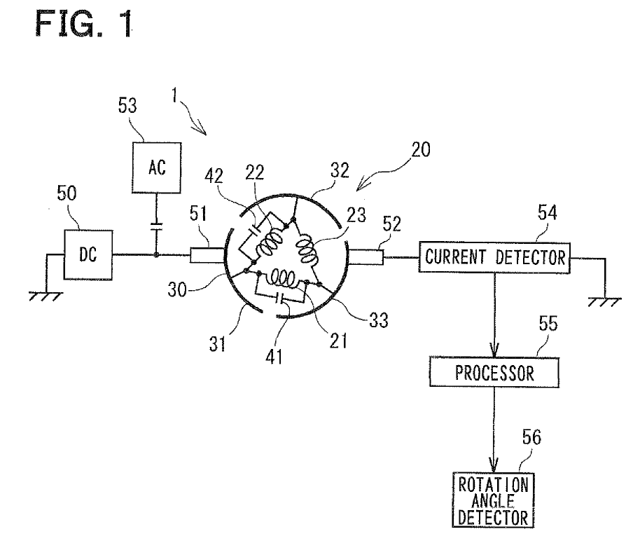

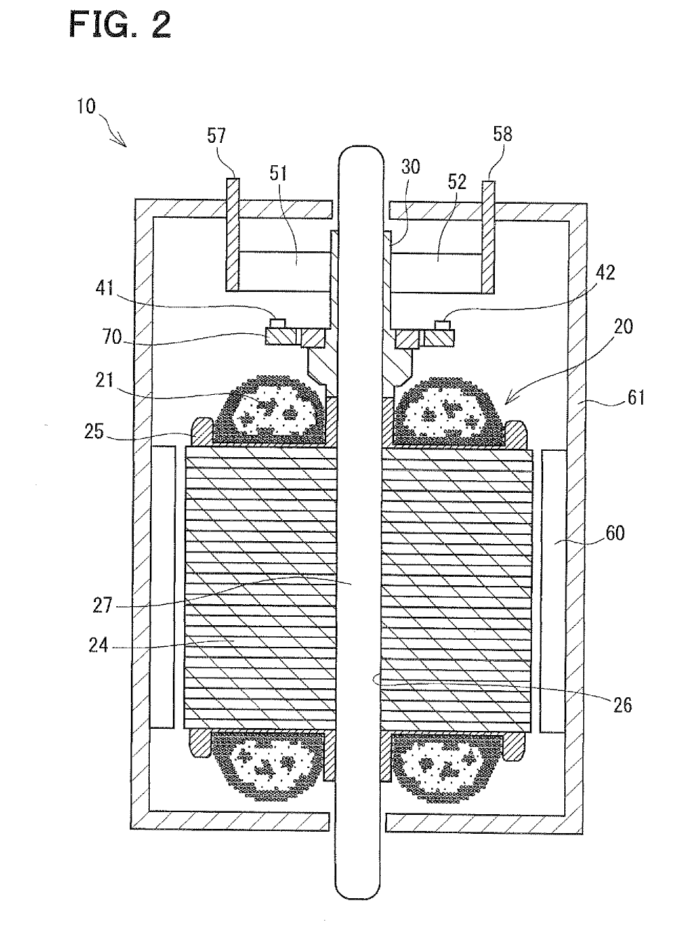

A rotation angle detecting device 1 of FIG. 1 is mounted to a motor 10 of FIG. 2, in an embodiment. The motor 10 corresponds to a drive unit. As shown in FIG. 2, the motor 10 includes a stator 60, a rotor 20, and a commutator 30. As shown in FIG. 1, the rotor 20 has three windings 21, 22, 23, and delta connection is conducted among the windings 21, 22, 23. Each end of the winding 21, 22, 23 is connected to a segment 31, 32, 33 of the commutator 30.

A first capacitor 41 is connected in parallel with the first winding 21. A second capacitor 42 is connected in parallel with the second winding 22. An electrostatic capacitance of the second capacitor 42 is smaller than that of the first capacitor 41.

Drive current is supplied to the winding 21, 22, 23 from a direct current power source 50 via a brush 51 and the commutator 30. The direct current power source 50 is superimposed with an alternate current power source 53.

A current detector 54 is arranged between a brush 52 and a ground, and detects current flowing through the motor 10. A signal processor 55 processes an amplitude change of the detected current into a pulse signal. A rotation angle detector 56 analyzes the pulse signal so as to detect a rotation angle of the rotor 20. A method of detecting the rotation angle will be described blow.

As shown in FIG. 2, the stator 60 has plural permanent magnets fixed to an inner wall of a cylindrical motor case 61 in a radial direction. Due to the permanent magnets, N-pole and S-pole are alternately generated in a circumference direction, so as to form a magnetic field. The rotor 20 is located on an inner side of the stator 60 in the radial direction through a predetermined clearance.

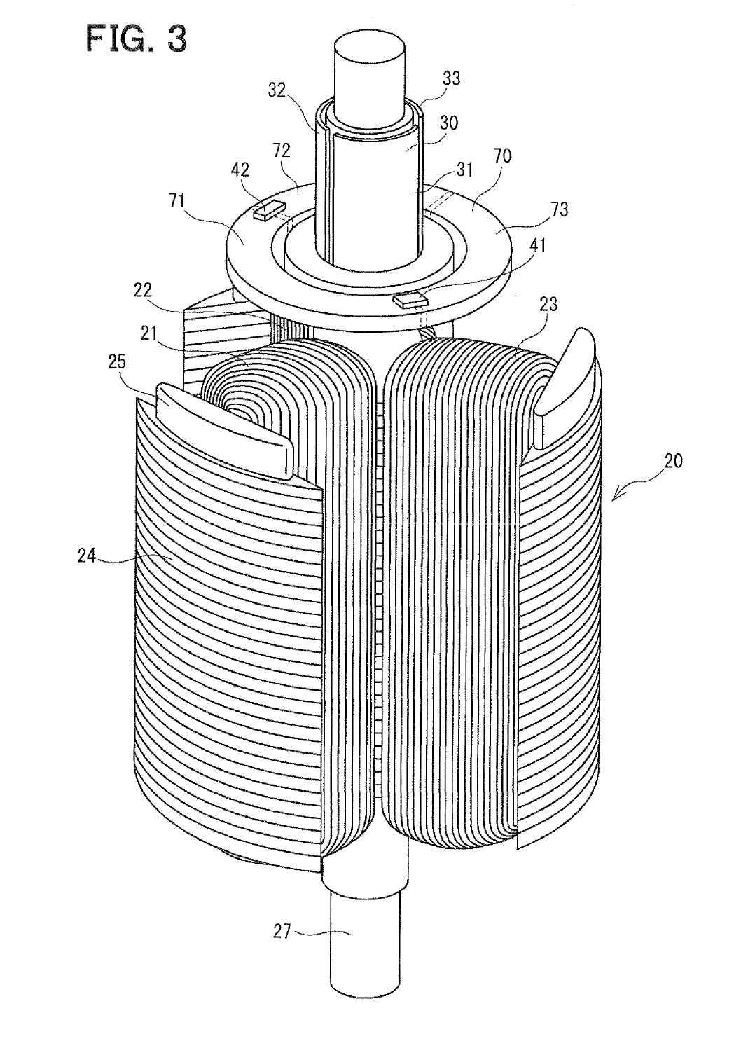

As shown in FIG. 3, the rotor 20 has a rotor core 24, an insulator 25 and the windings 21, 22, 23. The rotor core 24 is made of layered iron core, and forms three protruding poles, for example. The winding 21, 22, 23 is would on an outer side of the protruding pole through the insulator 25.

As shown in FIG. 2, a shaft 27 is fixed in a shaft hole 26 defined to extend in a center axis of the rotor core 24. Both ends of the shaft 27 in the axis direction are supported by the motor case 61 in a rotatable state. Therefore, the rotor 20 is rotatable relative to the motor case 61 and the stator 60.

The commutator 30 is fixed to an outer wall of the shaft 27 in the radial direction. A wiring to connect the winding 21, 22, 23 and the segment 31, 32, 33 of the commutator 30 is omitted in FIGS. 2 and 3. As shown in FIG. 3, a disk-like ring varistor 70 is arranged on an outer side of the commutator 30 in the radial direction.

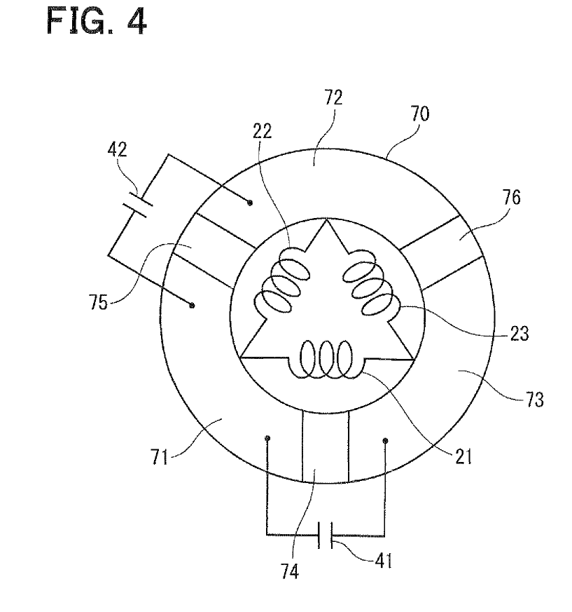

As shown in FIG. 4, the ring varistor 70 has three electrodes 71, 72, 73 and three resistors 74, 75, 76. The electrode 71, 72, 73 is electrically connected with the segment 31, 32, 33 of the commutator 30. The electrodes 71, 72, 73 are connected with each other through the resistor 74, 75, 76. Due to the ring varistor 70, current flows on the ground side even if a surge voltage is added, thereby noise can be reduced.

The first capacitor 41 is located between the first electrode 71 and the third electrode 73. The second capacitor 42 is located between the first electrode 71 and the second electrode 72. The first capacitor 41 is connected in parallel with the first winding 21, and the second capacitor 42 is connected in parallel with the second winding 22.

The brush 51, 52 is to be electrically connected to the segment 31, 32, 33 of the commutator 30. Electricity is supplied to the brush 51, 52 from the direct current power source 50 and the alternate current power source 53 through a terminal 57, 58 of FIG. 2. At this time, current flows through the windings 21, 22, 23, such that the rotor 20 is rotated.

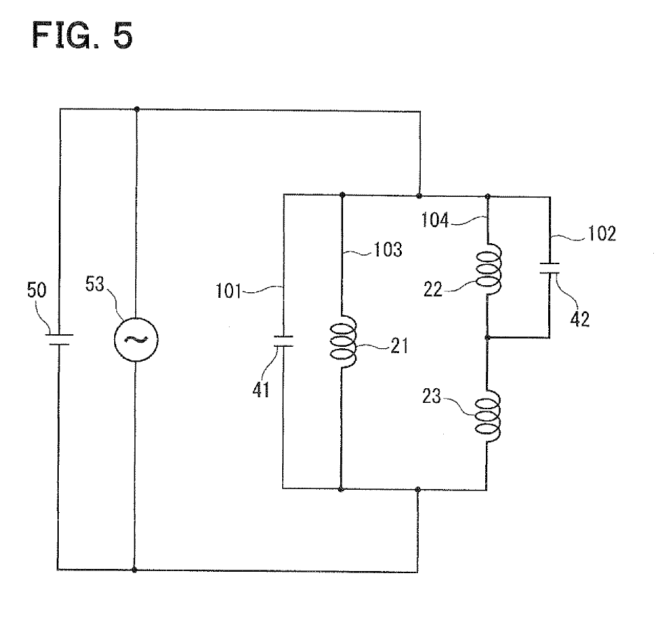

A method of detecting a rotation angle of the motor 10 will be explained. Every time when the motor 10 has a rotation of 60°, an electric circuit of the rotation angle detecting device 1 is changed among three circuits shown in FIGS. 5, 6 and 7, and the three circuits have impedances different from each other.

As shown in FIG. 8, the current detector 54 detects three pulsations having different amplitudes, while current flows through the three electric circuits in order.

When the first brush 51 contacts the first segment 31, and when the second brush 52 contacts the third segment 33, the motor 10 has the electric circuit of FIG. 5. At this time, direct-current component flows through third and fourth shunts 103, 104 without flowing through first and second shunts 101, 102. The first and second shunts 101, 102 have the first and second capacitors 41, 42, respectively. In contrast, alternate-current component mainly flows through the first shunt 101, because inductive reactance and frequency are proportional.

A capacitive reactance is in inverse proportion to the capacitance. Because the first capacitor 41 has the capacitance larger than that of the second capacitor 42, the first capacitor 41 has the capacitive reactance smaller than that of the second capacitor 42. Therefore, the current detector 54 detects a large-amplitude pulsation I in a time period T1-T2 of FIG. 8.

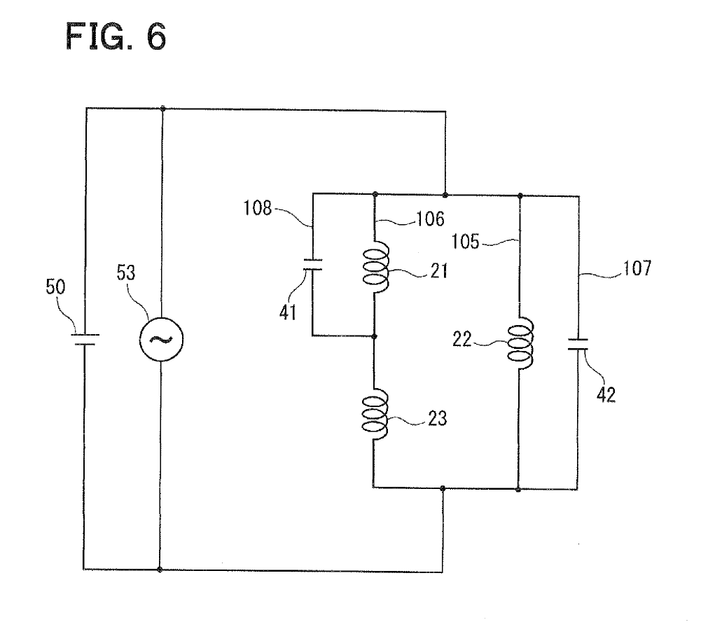

If the rotor 20 is rotated in a clockwise direction in FIG. 1, the first brush 51 contacts the first segment 31, and the second brush 52 contacts the second segment 32. At this time, the motor 10 has the electric circuit of FIG. 6. In the circuit of FIG. 6, direct-current component flows through fifth and sixth shunts 105 and 106, and alternate-current component mainly flows through a seventh shunt 107.

Because the second capacitor 42 has the capacitance smaller than that of the first capacitor 41, the second capacitor 42 has the capacitive reactance larger than that of the first capacitor 41. Therefore, when the current detector 54 detects a pulsation II in a time period T2-T3 of FIG. 8, the amplitude of the pulsation II is smaller than that of the pulsation I.

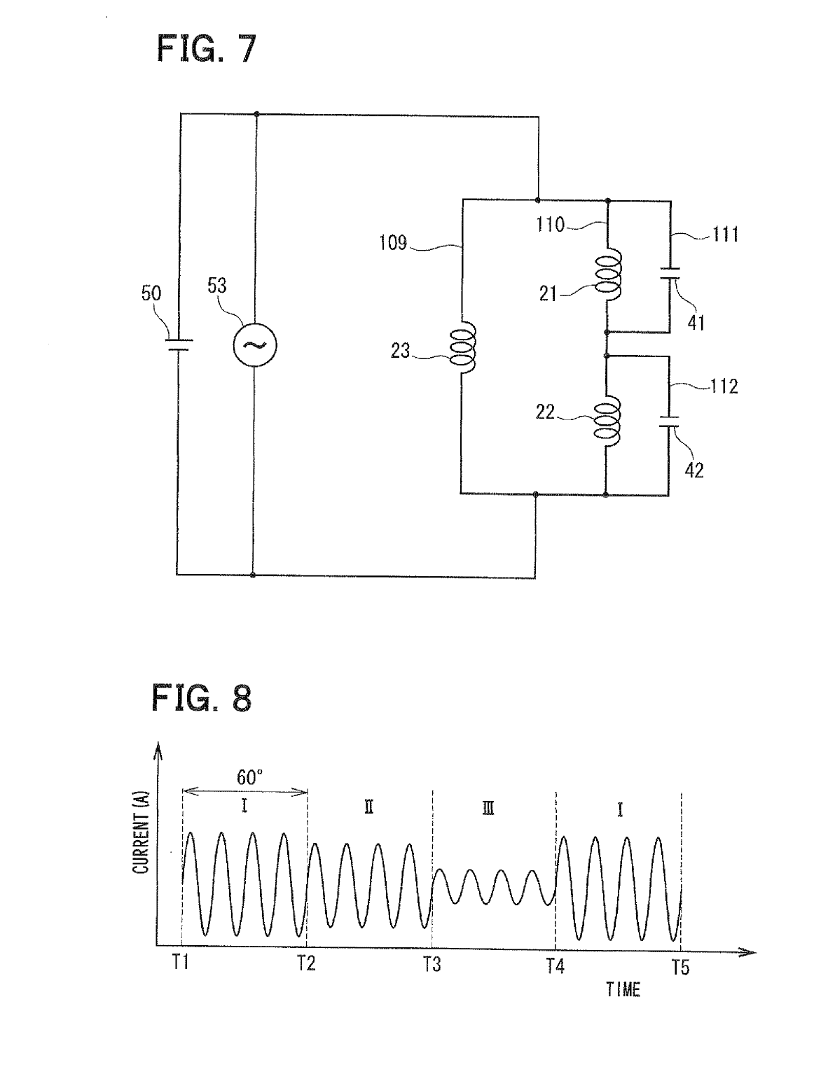

If the rotor 20 is further rotated in the clockwise direction in FIG. 1, the first brush 51 contacts the third segment 33, and the second brush 52 contacts the second segment 32. At this time, the motor 10 has the electric circuit of FIG. 7. In the circuit of FIG. 7, direct-current component flows through ninth and tenth shunts 109 and 110, and alternate-current component mainly flows through eleventh and twelfth shunts 111 and 112.

The first capacitor 41 is connected in serial with the eleventh shunt 111, and the second capacitor 42 is connected in serial with the twelfth shunt 112. Therefore, a sum of the capacitances between the first capacitor 41 and the second capacitor 42 becomes smaller, compared with the capacitor 41, 42. Thus, when the current detector 54 detects a pulsation III in a time period T3-T4 of FIG. 8, the amplitude of the pulsation III is smaller than that of the pulsation II.

If the rotor 20 is further rotated in the clockwise direction in FIG. 1, the first brush 51 contacts the third segment 33, and the second brush 52 contacts the first segment 31. At this time, the motor 10 has the electric circuit of FIG. 5, again. The current detector 54 detects the pulsation I in a time period T4-T5 of FIG. 8, and the pulsation I in the time period T4-T5 is approximately the same as the pulsation I in the time period T1-T2.

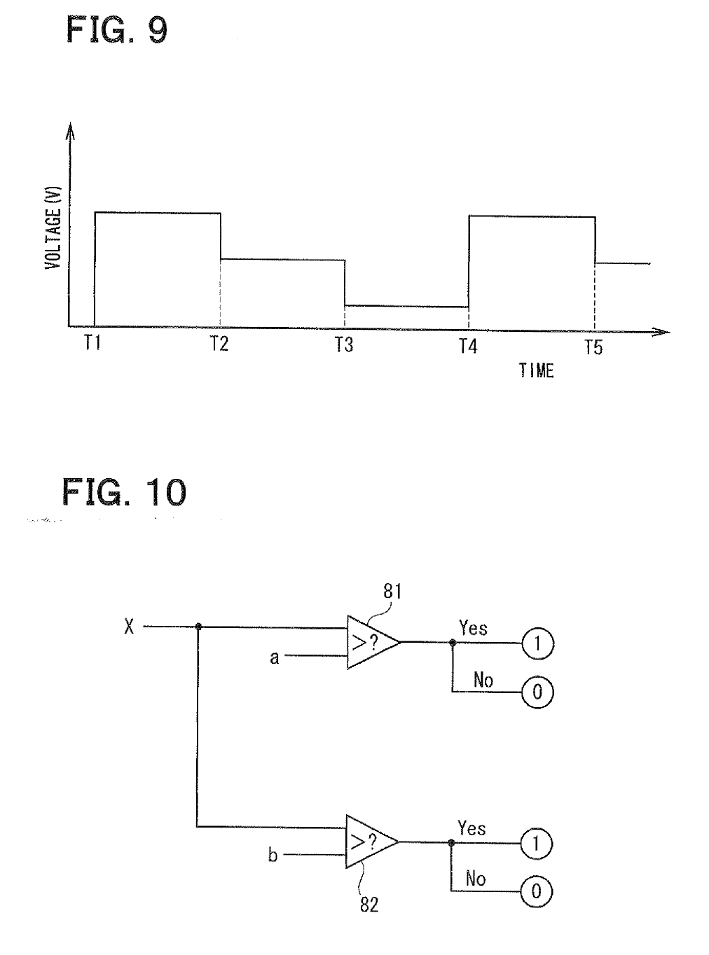

As shown in FIG. 9, the signal processor 55 converts the current detected by the current detector 54 into a pulse signal through AID conversion, rectification, smoothing and the like. The amplitude change is represented in a voltage difference of the pulse signal.

As shown in FIG. 10, the signal output from the signal processor 55 is input into comparison circuits 81, 82 of the rotation angle detector 56. The first comparison circuit 81 compares a signal X output from the processor 55 with a threshold “a”. When the signal X is equal to or larger than the threshold “a” the first comparison circuit 81 outputs “1”. When the signal X is smaller than the threshold “a”, the first comparison circuit 81 outputs “0”.

At the same time, the second comparison circuit 82 compares the signal X with a threshold “b”. When the signal X is equal to or larger than the threshold “b”, the second comparison circuit 82 outputs “1”. When the signal X is smaller than the threshold “b”, the second comparison circuit 82 outputs “0”.

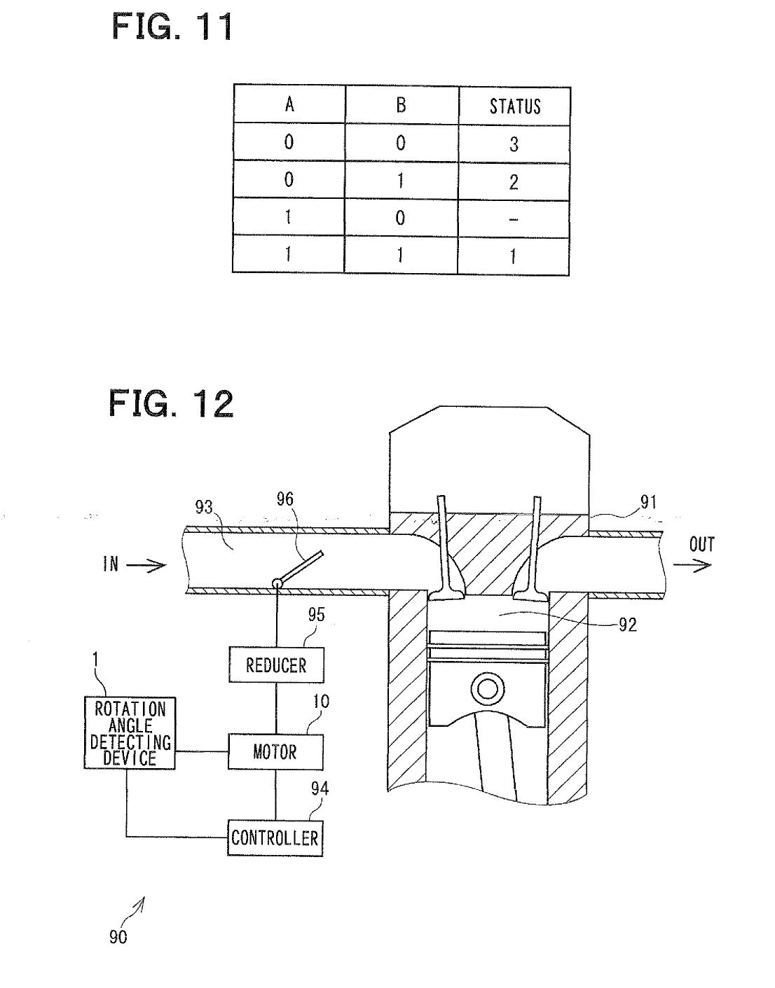

The rotation angle detector 56 applies the outputs of the first and second comparison circuits 81 and 82 into a truth table shown in FIG. 11. The truth table has a A-block and a B-block. The output of the first comparison circuit 81 is applied into the A-block, and the output of the second comparison circuit 82 is applied into the B-block.

The rotation angle detector 56 determines the signal X to have a third status when the A-block corresponds to “0” and when the B-block corresponds to “0”. The rotation angle detector 56 determines the signal X to have a second status when the A-block corresponds to “0” and when the B-block corresponds to “1”. The rotation angle detector 56 determines the signal X to have a first status when the A-block corresponds to “1” and when the B-block corresponds to “1”.

The rotation angle detector 56 detects the rotor 20 to have a rotation in a normal direction, if the signal X is changed in order of the first status, the second status and the third status, if the signal X is changed in order of the second status, the third status and the first status, or if the signal X is changed in order of the third status, the first status and the second status.

The rotation angle detector 56 detects the rotor 20 to have a rotation in an adverse direction, if the signal X is changed in order of the first status, the third status and the second status, if the signal X is changed in order of the third status, the second status and the first status, or if the signal X is changed in order of the second status, the first status and the third status.

Further, the rotation angle detector 56 counts a number that the status of the signal X is changed. A value of the counting is added when the rotor 20 has a normal direction rotation, and is subtracted when the rotor 20 has an adverse direction rotation. That is, the value of the counting is increased or decreased in accordance with the rotation direction.

Thus, the rotation angle of the rotor 20 can be calculated. For example, a rotation angle of an intake air control valve 96 of FIG. 12 can be calculated in this method. The valve 96 corresponds to an object to be driven. The processor 55 and the rotation angle detector 56 correspond to a rotation direction detector to detect a rotation direction of a rotor. Further, the processor 55 and the rotation angle detector 56 correspond to a rotation angle calculator to detect a rotation angle of the rotor or an object to be driven to by the rotor.

As shown in FIG. 12, the motor 10 having the rotation angle detecting device 1 is mounted to an intake air control system 90. The intake air control system 90 is arranged in an intake passage 93 to supply intake air to a combustion chamber 92 of an engine 91. The intake air control system 90 has a controller 94, the motor 10, a reducer 95, and the intake air control valve 96.

The controller 94 applies drive current to the motor 10 based on a control program or control logic, so as to rotate the motor 10. Due to the reducer 95, the rotation of the motor 10 can be made slow into 1/40, for example, and is transmitted to the intake air control valve 96. The intake air control valve 96 controls a passage cross-section area of the intake passage 93 by controlling the rotation angle. Therefore, the intake air control system 90 can form vortex air flow in the combustion chamber 92 in accordance with an engine operation status.

The rotation angle detecting device 1 can detect a rotation angle variation of the motor 10 by a unit of 60°. Therefore, the rotation angle variation can be detected with a resolution of 1.5°, when the rotation angle of the intake air control valve 96 is transmitted with a reduction ratio 40. The controller 94 applies drive current to the motor 10 based on the detection result of the rotation angle detecting device 1, such that the intake air control valve 96 can have a rotation with a target angle.

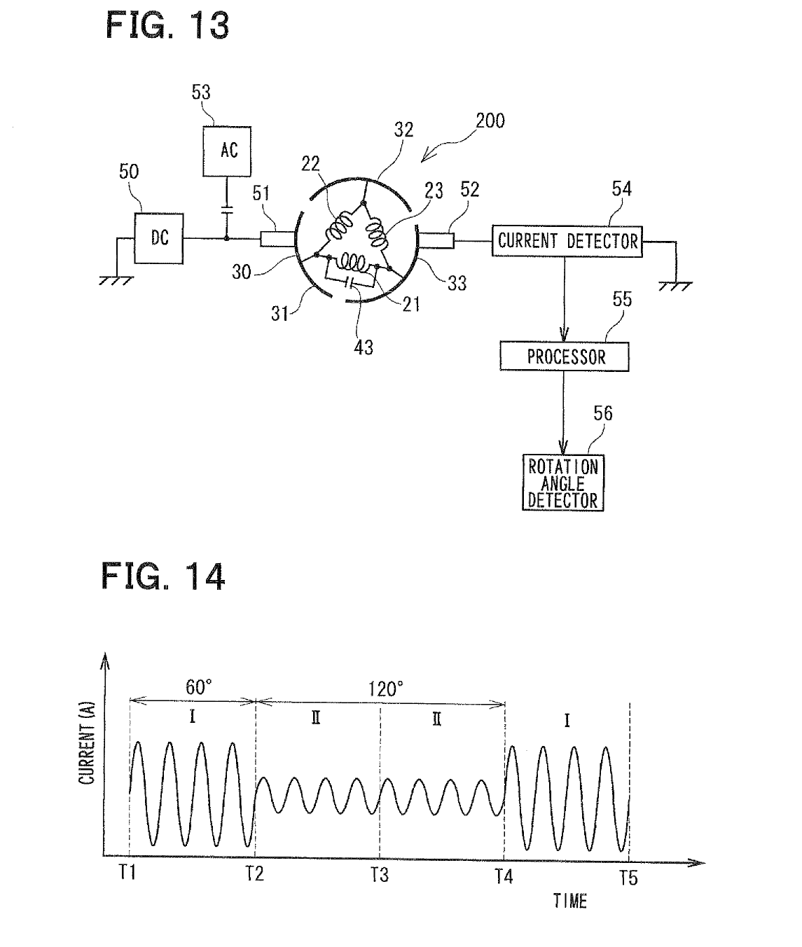

A comparison example is shown in FIGS. 13 and 14, relative to the rotation angle detecting device 1 of the present invention.

As shown in FIG. 13, in the comparison example, a rotor 200 has three windings 21, 22, 23, and a capacitor 43 connected in parallel with the first winding 21. No capacitor is connected to the second winding 22 and the third winding 23. Every time when the rotor 200 has a rotation of 60° or 120°, a circuit is changed between two circuits having different impedances.

As shown in FIG. 14, the current detector 54 detects two pulsations having different amplitudes while current flows through the two circuits.

When the first brush 51 contacts the first segment 31, and when the second brush 52 contacts the third segment 33, as shown in FIG. 13, the current detector 54 detects a pulsation I with a large amplitude, in a time period T1-T2 of FIG. 14.

When the rotor 200 is rotated in a clockwise direction in FIG. 13, the first brush 51 contacts the first segment 31, and the second brush 52 contacts the second segment 32. At this time, the current detector 54 detects a pulsation II in a time period T2-T3, and an amplitude of the pulsation II is smaller than that of the pulsation I.

When the rotor 200 further has a rotation of 60°, the first brush 51 contacts the third segment 33, and the second brush 52 contacts the second segment 32. At this time, the current detector 54 detects the pulsation II in a time period T3-T4, and the pulsation II has approximately the same amplitude as that in the time period 12-T3.

When the rotor 200 further has a rotation of 60°, the first brush 51 contacts the third segment 33, and the second brush 52 contacts the first segment 31. At this time, the current detector 54 detects the pulsation I in a time period T4-T5, and the pulsation I has approximately the same amplitude as that in the time period T1-T2.

The signal processor 55 converts the amplitude change of the current into two different pulse signals having different voltages. The rotation angle detector 56 counts a number that the pulse signal is changed in a predetermined period, so as to detect the rotation angle of the rotor 200. Therefore, the rotation angle detecting device of the comparison example can detect the rotation angle of the motor 200 by a unit of 60° or 120°. However, the rotation direction is difficult to be detected in the comparison example.

According to the embodiment of the present invention, the two capacitors 41, 42 having different capacitances are connected to the windings 21, 22, respectively, in the parallel state. Therefore, the current detector 54 can detect the three different pulsations with different amplitudes. A change of the pulsation detected by the current detector 54 is converted into a pulse signal by the processor 55. The rotation angle detector 56 determines the pulse signal into three statuses.

The rotation angle detector 56 detects the rotor 20 to have a rotation in a normal direction, if the signal X is changed in order of the first status, the second status and the third status.

The rotation angle detector 56 detects the rotor 20 to have a rotation in an adverse direction, if the signal X is changed in order of the first status, the third status and the second status.

Further, the rotation angle detector 56 counts the number that the status of the signal X is changed. The rotation angle detector 56 increases or decreases a value of the counting in accordance with the rotation direction, such that the rotation angle of the rotor 20 or the intake air control valve 96 can be computed.

The capacitor 41, 42 is arranged between the electrodes 71, 72, 73 of the ring varistor 70. Therefore, attachment of the capacitor 41, 42 can be easily and accurately performed.

In the intake air control system 90, when intake air flows toward the combustion chamber 92, a force is applied to a face of the intake air control valve 96 opposite from the combustion chamber 92. Further, if air flows from the combustion chamber 92 in a direction opposite from the normal direction, a force is applied to a face of the intake air control valve 96 adjacent to the combustion chamber 92.

The rotation direction of the rotor 200 is undetectable in the comparison example, since the current detector 54 detects only two different amplitudes. In contrast, according to the embodiment, it is possible to detect the rotation direction of the rotor 20 or the intake air control valve 96, even if the rotation angle is influenced by air flowing through the intake passage 93.

In the comparison example, the rotation angle of the intake air control valve 96 transmitted with the reduction ratio 40 is detected with the resolution of 3°, since the rotation angle of the motor is detected by unit of 60° or 120°.

In contrast, according to the embodiment, the resolution can be increased double, because the rotation angle of the intake air control valve 96 can be detected with the resolution of 1.5°. Therefore, a phase control of the intake air control valve 96 of the intake air control system 90 can be accurately performed, due to the rotation angle detecting device 1. Thus, the intake air control system 90 can form the optimum vortex air flow in the combustion chamber 92. Accordingly, emission can be reduced, and fuel consumption can be reduced.

The rotation angle detecting device 1 is not limited to be used for the intake air control system 90. The rotation angle detecting device 1 may be used for other system using a brush motor.

The rotor 20 has the three windings 21, 22, 23 with delta connection in the above embodiment. Alternatively, the motor 10 may have a rotor with star connection.

The pole number of the rotor 20 corresponding to the windings 21, 22, 23 may be more than three. The number of the capacitors 41, 42 may be more than two, provided the capacitors 41, 42 have different capacitances. For example, it is also possible to arrange capacitors relative to all the windings 21, 22, 23 of the rotor 20 in the parallel connection.

The capacitor 41, 42 is connected between the electrode 71, 72, 73 of the ring varistor 70 in the above embodiment. Alternatively, the capacitor 41, 42 may be connected between the segments 31, 32, 33 of the commutator 30 so as to be parallel with the winding 21, 22, 23 of the rotor 20.

The amplitude change is changed into the signals having different voltages by the processor 55. Alternatively, the processor 55 may be eliminated. In this case, the rotation direction and the rotation angle of the rotor 20 may be directly detected by a change of pulsation amplitude detected by the current detector 54.

Such changes and modifications are to be understood as being within the scope of the present invention as defined by the appended claims.

What is claimed is:

1. A rotation angle detecting device to detect a rotation angle of a motor, the motor including a stator to form a magnetic field, a rotor having windings, and a brush, the rotor being rotated relative to the stator by electricity supplied to the windings through the brush, the rotation angle detecting device comprising:
a first capacitor connected in parallel with a first winding of the windings;
a second capacitor connected in parallel with a second winding of the windings, the second capacitor having a capacitance different from a capacitance of the first capacitor;
a direct current power source to supply electricity to the windings;
an alternate current power source superimposed with the direct current power source;
a current detector to detect a current flowing through a circuit defined by the motor;
a rotation direction detector to detect a rotation direction of the rotor based on an order of amplitude change of the current detected by the current detector;
a rotation angle calculator to count a number of the amplitude changes, wherein
the rotation angle calculator increases or decreases a value of the counting in accordance with the rotation direction detected by the rotation direction detector, so as to calculate a rotation angle of the rotor or a rotation angle of an object to be driven by the motor.

2. The rotation angle detecting device according to claim 1, wherein
the rotation direction detector has
a signal processor to convert the amplitude change into pulse signals having different voltages, and
a rotation angle detector to determine a state of the pulse signal into three different statuses, wherein
the rotation angle detector detects the rotor to have a rotation in a normal direction when the status is changed in order of a first status, a second status and a third status, and
the rotation angle detector detects the rotor to have a rotation in an adverse direction when the status is changed in order of the first status, the third status and the second status.

3. The rotation angle detecting device according to claim 1, further comprising:
a commutator having segments to be electrically connected to the brush; and
a varistor having electrodes electrically connected to the segments, respectively, wherein
each of the first capacitor and the second capacitor is arranged between the electrodes of the varistor.

4. The rotation angle detecting device according to claim 1, further comprising:
a commutator having segments to be electrically connected to the brush, wherein
each of the first capacitor and the second capacitor is arranged between the segments of the commutator.

5. A drive unit comprising:
a stator to form a magnetic field;
a rotor to be rotated relative to the stator, the rotor having at least three windings;
a commutator electrically connected to the windings of the rotor;
at least two brushes to be electrically connected to the commutator;
a first capacitor connected in parallel with a first winding of the windings;
a second capacitor connected in parallel with a second winding of the windings, the second capacitor having a capacitance different from a capacitance of the first capacitor;
a direct current power source to supply electricity to the windings;
an alternate current power source superimposed with the direct current power source;
a current detector to detect a current flowing through a circuit defined between the two brushes;
a rotation direction detector to detect a rotation direction of the rotor based on an order of amplitude change of the current detected by the current detector; and
a rotation angle calculator to count a number of the amplitude changes, wherein
the rotation angle calculator increases or decreases a value of the counting in accordance with the rotation direction detected by the rotation direction detector, so as to calculate a rotation angle of the rotor or a rotation angle of an object to be driven by the rotor.

6. The drive unit according to claim 5, wherein
the rotation direction detector has
a signal processor to convert the amplitude change into pulse signals having different voltages, and
a rotation angle detector to determine a state of the pulse signal into three different statuses, wherein
the rotation angle detector detects the rotor to have a rotation in a normal direction when the status is changed in order of a first status, a second status and a third status, and
the rotation angle detector detects the rotor to have a rotation in an adverse direction when the status is changed in order of the first status, the third status and the second status.

7. The drive unit according to claim 5, further comprising:
a varistor having electrodes, wherein
the commutator has segments to be electrically connected to the brush,
the electrodes of the varistor are electrically connected to the segments of the commutator, respectively, and
each of the first capacitor and the second capacitor is arranged between the electrodes of the varistor.

8. The drive unit according to claim 5, wherein
the commutator has segments to be electrically connected to the brush, wherein
each of the first capacitor and the second capacitor is arranged between the segments of the commutator.
